(19) United States
(12) Patent Application Publication
(10) Pub. No.: US 2024/0427363 A1
(43) Pub. Date: Dec. 26, 2024

(54) POLARIZATION OF ELECTRONIC CIRCUITS INCLUDING RADIOFREQUENCY ANALOG CIRCUITS

(71) Applicant: STMicroelectronics International N.V., Geneva (CH)

(72) Inventor: Jean-Yves COUET, Saint Martin Le Vinoux (FR)

(73) Assignee: STMicroelectronics International N.V., Geneva (CH)

(21) Appl. No.: 18/745,299

(22) Filed: Jun. 17, 2024

(30) Foreign Application Priority Data
Jun. 26, 2023 (FR) 2306660

(51) Int. Cl. G05F 1/56

(52) U.S. Cl. CPC G05F 1/56

(57) ABSTRACT

A method for polarizing at least one first electronic circuit based on a first direct polarization current, the at least one first circuit being powered by a supply voltage having actual values dispersed around a rated value, the at least one first circuit having at least one first physical parameter whose value could undergo a variation resulting from the dispersion of voltage values, the method comprising an open-loop compensation of the dispersion of the voltage value including elaborating a first corrected current based on a reference current and a first correction coefficient determined from the variation of the value of the at least one first physical parameter, resulting from the dispersion of the voltage values, and elaborating the first polarization current based on the first corrected current.

### BACKGROUND

### Technical Field

Embodiments and implementations relate to the polarization of electronic circuits with direct polarization currents, in particular analog circuits made according to the BiCMOS or CMOS technology and used in radiofrequency (RF) integrated circuits, for example RF amplifiers, mixers, phase shifters.

### Description of the Related Art

The performances of these circuits considerably depend on these polarization currents.

Yet, variations of the supply voltage are a major cause of variations of these polarization currents, thereby leading to a degradation of the performances of these circuits, in particular in terms of gain.

In general, to get rid of the variations of the power supply, one could either cascode the current sources or equip the entire integrated circuit with a low drop out type voltage regulator (“LDO: Low Drop Out”) delivering the supply voltage.

Yet, these two solutions have the drawback of reducing the value of the supply voltage delivered to the different components of the integrated circuit which might turn out to be very constraining and even unacceptable when the supply voltage powering the regulator has a low value.

### BRIEF SUMMARY

Hence, there is a need to reduce the impact of the variations of the supply voltage on the polarization currents on the entirety of the integrated circuit, and that being so without imposing constraints on the supply voltage.

According to one aspect, an integrated circuit is provided comprising at least one first electronic circuit configured to be powered by a supply voltage and to be polarized based on a first direct polarization current.

The supply voltage possibly may have actual values dispersed around a rated value.

Said at least one first circuit has at least one first physical parameter, for example a gain, whose value could undergo a variation (or dispersion) resulting from said dispersion of voltage values.

According to this aspect, the integrated circuit comprises a polarization centralized circuit comprising a first compensation circuit configured to perform an open-loop compensation of said dispersion of the voltage values.

This open-loop compensation includes elaborating a first corrected current based on a reference current and a first correction coefficient determined from the variation (or dispersion) of the value of said at least one first physical parameter resulting from said dispersion of the voltage values.

Thus, the first correction coefficient is advantageously adjusted according to the sensitivity of said at least one first circuit to the variations of the voltage, this sensitivity being reflected by a variation of the first physical parameter, for example the gain, of the first circuit.

For example, in the case where the first physical parameter is the gain of the first circuit, a first circuit that would feature a gain variation of 0.5 dB when the voltage varies from 1.7V to 1.9V for example would be assigned a first coefficient higher than a first circuit that would feature a variation of only 0.2 dB for the same variations (or dispersion) of values of the voltage.

The polarization centralized circuit also includes a first current replication circuit, for example of the current mirror type, configured to elaborate the first polarization current based on the first corrected current.

An open-loop centralized pre-compensation, and therefore a centralized pre-correction, of the polarization current and possibly of all polarization currents (when there are several first electronic circuits), allows obtaining a lower sensitivity of the polarization current(s) to the variations of the supply voltage.

According to one embodiment, the polarization centralized circuit includes a reference current source configured to deliver the reference current.

Moreover, the first compensation circuit is configured to:
determine a voltage difference between the actual value of the supply voltage and its rated value;
transform this voltage difference into a first correction current using the first correction coefficient; and
inject this first correction current in the reference current source to obtain the first corrected current.

According to one embodiment, the integrated circuit comprises a reference voltage source, for example a “band gap” type voltage configured to deliver a reference voltage.

And the first compensation circuit comprises for example:
a first transconductance operational amplifier having a first input connected to the reference voltage source and an output looped back on a second input of this first transconductance operational amplifier;
a first current replication block connected to the output of the first transconductance operational amplifier and having a replication factor adjustable according to the first correction coefficient; and
a voltage divider resistive bridge having an input for receiving the supply voltage and an output.

Moreover, this divider bridge is dimensioned so as to deliver on its output a voltage equal to the reference voltage when the supply voltage present at its input, has its rated value.

According to this embodiment, the first compensation circuit also comprises:
a second transconductance operational amplifier having a first input connected to the output of the divider bridge and an output looped back on a second input of this second transconductance operational amplifier; and
a second current replication block connected to the output of the second transconductance operational amplifier and having said replication factor adjustable according to the first correction coefficient.

The node connected to the respective outputs of the two current replication blocks is able to deliver the first correction current.

The reference current source and the first current replication circuit (which deliver the first polarization current(s)) are connected to said node.

Although this is not essential, the first current replication block may include two cascoded first current replication stages and the second current replication block may include two cascoded second current replication stages.

The use of cascoded current replication (or mirror) stages allows making the polarization currents even less sensitive to the variations of the supply voltage.

Advantageously, the first correction parameter is programmable.

For example, it may be stored in a register and the being able to modify it allows adapting to different type of electronic circuits and/or applications.

As indicated hereinbefore, the first physical parameter is, for example, the gain of the first circuit.

The integrated circuit may comprise several first circuits configured to be powered by the supply voltage and to be polarized based on respective first direct polarization currents.

And the first current replication circuit is configured to elaborate these respective first polarization currents based on said corrected current.

The first circuits form, for example, a radiofrequency emission or reception chain and the first physical parameter is, for example, the gain of the emission or reception chain.

According to one embodiment, the integrated circuit further comprises several second circuits configured to be powered by the supply voltage and to be polarized based on respective second direct polarization currents.

The first circuits form, for example, a radiofrequency emission chain and the second circuits form, for example, a radiofrequency reception chain having a gain forming a second physical parameter, whose value could undergo a variation resulting from said dispersion of voltage values.

The polarization centralized circuit comprises:
a second compensation circuit, similar to the first compensation circuit, configured to perform an open-loop compensation of said dispersion of the voltage values including elaborating a second corrected current based on the reference current and a second correction coefficient determined from the variation of the value of said second physical parameter, resulting from said dispersion of the voltage values; and
a second current replication circuit configured to elaborate the second polarization current based on the second corrected current.

The second compensation circuit and the second current replication circuit, may be distinct from the first compensation circuit and from the first current replication circuit, respectively.

Alternatively, since the transmission and reception chains function in practice with a time-division multiplexing, the second compensation circuit and the second current replication circuit could be combined with the first compensation circuit and the first current replication circuit, so as to form the same compensation circuit and the same current replication circuit, sequentially implemented by using the first correction coefficient and the second coefficient sequentially, according to the time-division multiplexing.

According to another aspect, a method is provided for polarizing at least one first electronic circuit based on a first direct polarization current, said at least one first circuit being powered by a supply voltage having actual values dispersed around a rated value, said at least one first circuit having at least one first physical parameter whose value could undergo a variation resulting from said dispersion of voltage values, the method comprising:
an open-loop compensation of said dispersion of the voltage values, including elaborating a first corrected current based on a reference current and a first correction coefficient determined from the variation of the value of said at least one first physical parameter, resulting from said dispersion of the voltage values; and
elaborating the first polarization current based on the first corrected current.

According to one implementation, the method comprises delivering a reference current by a reference current source and said compensation comprises:
determining a voltage difference between the actual value of the supply voltage and its nominal value;
transforming this voltage difference into a first correction current using the first correction coefficient; and
injecting this first correction current in the reference current source to obtain the first corrected current.

According to another aspect, a method is provided for determining the value of the first correction coefficient used in the integrated circuit as defined hereinbefore or in the method as defined hereinbefore, comprising, after manufacture of the integrated circuit, a measurement of the variation of the first physical parameter caused by the dispersion of the values of the supply voltage, for different values of the first correction coefficient, and a selection of the value of the first correction coefficient corresponding to a value desired for the variation of the first physical parameter.

### BRIEF DESCRIPTION OF THE SEVERAL VIEWS OF THE DRAWINGS

Other advantages and features of the disclosure will appear upon examining the detailed description of non-limiting embodiments and implementations, and from the appended drawings wherein:

FIG. 1 shows an integrated circuit including a chain of first circuits forming for example a radiofrequency transmission chain;

FIG. 2 shows a reference current based on which a polarization effective current of the circuit is determined;

FIG. 3 illustrates an implementation of a method for polarizing each first circuit based on a corresponding first direct polarization current;

FIG. 4 shows an integrated circuit including a reference voltage source;

FIG. 5 shows a first current replication block including two cascaded first current replication stages;

FIG. 6 shows an example of a method for determining a value of a first correction coefficient; and

FIG. 7 shows an integrated circuit including both a radiofrequency emission chain and a radiofrequency reception chain.

### DETAILED DESCRIPTION

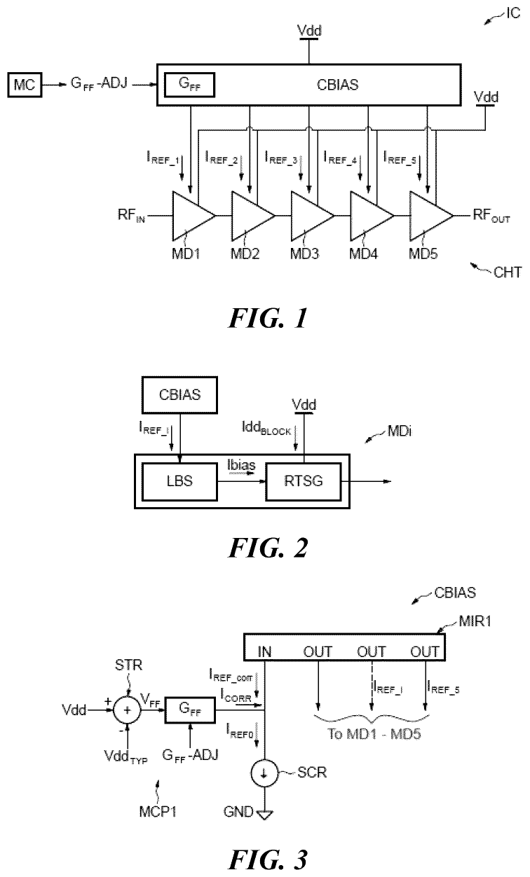

In FIG. 1, the reference IC refers to an integrated circuit including in this case a chain of first circuits MD1-MD5 forming for example a radiofrequency transmission chain.

The input signal of the chain bears the reference RF_{IN} and the output signal RF_{OUT}.

Each first circuit MDi is powered by a supply voltage Vdd which could have actual values dispersed around a nominal value.

For example, the rated value may be equal to 1.8 volts and the actual values may be comprised between 1.7 volts and 1.9 volts for example.

Moreover, each first circuit MDi is intended to be polarized based on a first direct polarization current I_{REF_i}.

The polarization currents I_{REF_i} are delivered by a polarization centralized circuit CBIAS whose structure and function will be reviewed in more details hereinafter.

A first physical parameter, for example the gain, i.e., the RF_{OUT}/RF_{IN} ratio, is assigned to the transmission chain CHT, whose value could undergo a variation or dispersion resulting from the dispersion of the voltage values of the supply voltage Vdd.

Yet, as of now, we could indicate that the polarization centralized circuit CBIAS comprises:
a first compensation circuit configured to perform an open-loop compensation of the dispersion of the voltage values, this open-loop compensation including elaborating a first corrected current based on a reference current and a first correction coefficient G_{FF} determined from the variation of the value of the first physical parameter, in this case the gain of the transmission chain CHT, resulting from said dispersion of the voltage values.

The polarization centralized circuit also comprises a first current replication circuit configured to elaborate each polarization current I_{REF_i} based on the first corrected current.

This first correction coefficient G_{FF}, for example stored in a register RG, is constant but could be programmable by a control circuit MC, for example a microcontroller of the integrated circuit IC using a digital control word G_{FF}-ADJ.

Although the polarization current I_{REF_i} could actually be the polarization current of the circuit MDi, it could, as illustrated in FIG. 2, be a reference current based on which the polarization effective current of the circuit MDi will be elaborated.

Indeed, in general, and is particularly the case for radiofrequency circuits, a circuit MDi may comprise, as illustrated in FIG. 2, a local polarization circuit LBS including a current replication circuit based on NMOS and/or PMOS transistors, intended to deliver the polarization effective current IBIAS based on the current I_{REF_i}, at the radiofrequency stage RTSG of this circuit MDi, this radiofrequency stage RTSG being powered by the supply voltage Vdd and receiving the current Idd_BLOCK.

In this case, the current I_{REF_i} may be considered as a reference current.

That being so, in the rest of the text, and for terminological consistency, it will still be referred to by the expression “first polarization current”.

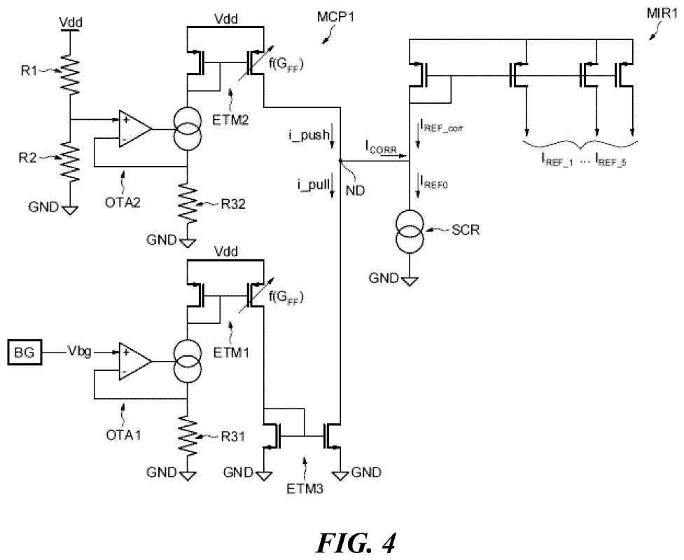

Reference is now made more particularly to FIGS. 3 and 4 to describe in more details an example of a structure of the first compensation circuit MCP1 and of the first current replication circuit MIR1.

FIG. 3 also illustrates an implementation of a method for polarizing each first circuit MDi based on the corresponding first direct polarization current I_{REF_i}.

The open-loop compensation of the dispersion of the values of the supply voltage Vdd includes, as indicated hereinabove,
elaborating, by the first compensation circuit MCP1, a first corrected current I_{REF_corr} based on a reference current I_{REF0} and the first correction coefficient G_{FF}, and
elaborating, by the current replication circuit MIR1, each first polarization current I_{REF_i} based on the first corrected current I_{REF_corr}.

The reference current I_{REF0} is delivered by a reference current source SCR.

The open-loop compensation comprises determining a voltage difference V_{FF} (schematically symbolized by a subtractor STR) between the actual value of the supply voltage Vdd and its rated value Vdd_{TYP}.

This voltage difference V_{FF} is transformed into a first correction current I_{CORR} using the first correction coefficient G_{FF}.

And, this first correction current I_{CORR} is injected in the reference current source SCR to obtain the first corrected current I_{REF_corr}.

This first corrected current is delivered at the input IN of the first current replication circuit MIR1 and the different first polarization currents I_{REF_i} are delivered on the outputs OUT of the first current replication circuit MIR1.

In FIG. 4, one could see that the integrated circuit includes a reference voltage source BG, for example a bandgap voltage configured to deliver a reference voltage Vbg, typically in the range of 1.2 volts.

In this embodiment, the first compensation circuit MCP1 includes a first transconductance operational amplifier, whose structure is conventional and known per se, bearing the reference OTA1.

This first transconductance operational amplifier OTA1 has:
a first input+connected to the reference voltage source BG to receive the reference voltage Vbg; and
an output looped back on a second input—of this first transconductance operational amplifier OTA1.

The output of this first transconductance operational amplifier OTA1 is also connected to the mass GND by a resistor R31.

Moreover, the first compensation circuit MCP1 includes a first current replication block ETM1 whose input s connected to the output of the transconductance amplifier OTA1 and having an adjustable replication factor f (G_{FF}) according to the first correction coefficient G_{FF}.

In practice, depending on the value of this first correction coefficient G_{FF}, more or less PMOS transistors will be used in the first current replication block ETM1.

The current delivered by this first block ETM1 is replicated in another current replication block ETM3 so as to pull a current i_pull at the ground GND.

The first compensation circuit MCP1 also includes a voltage divider resistive bridge R1, R2 having an input for receiving the supply voltage Vdd and an output (common node between the resistors R1 and R2).

This voltage divider ridge is dimensioned so as to deliver on its output a voltage equal to the reference voltage Vbg when the supply voltage Vdd present on its input has a rated value Vdd_{TYP} (1.8 volts for example).

The first compensation circuit MCP1 also includes a second transconductance operational amplifier OTA2.

This second transconductance operational amplifier OTA2 has:
a first input+connected to the output of the divider bridge R1, R2,
and an output looped back on a second input—of this second transconductance operational amplifier OTA2.

Moreover, the output of this second amplifier OTA2 is also connected to the ground GND via a resistor R32.

The first compensation circuit MCP1 also includes a second current replication block ETM2 connected to the output of the second transconductance operational amplifier OTA2 and having the same replication factor as that of the first block ETM1, which replication factor is, herein again, adjustable based on the first correction coefficient G_{FF}.

This block ETM2 delivers the current i_push.

And, the node MD connected to the respective outputs of the two current replication blocks ETM1 and ETM2, delivers the first correction current I_{CORR} which will be injected in the reference current source SCR.

This first correction current I_{CORR} is equal to i_push-i_pull.

The first current replication circuit MIR1 replicates the corrected current I_{REF_corr} so as to deliver the first polarization current I_{REF_1} . . . . I_{REF_5} with variable replication factors.

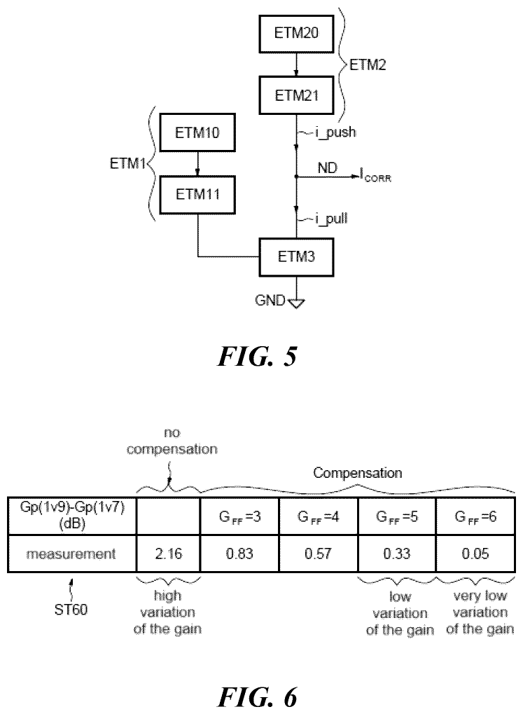

Although this is not necessary, it is preferable, in order to further reduce sensitivity of the polarization currents to the variations of the supply voltage, that the first current replication block ETM1 includes two cascaded first current replication stages ETM10, ETM11 (FIG. 5).

Similarly, it is particularly advantageous that the second current replication block also includes two cascaded current replication stages ETM20, ETM21.

Reference is now made more particularly to FIG. 6 to illustrate an example of a method for determining the value of the first correction coefficient G_{FF} used in the integrated circuit as described hereinbefore or in the method as described hereinbefore.

This determination method includes, after manufacture of the integrated circuit, measuring, for example in the laboratory, the variation of the first physical parameter Gp (herein the gain of the transmission chain CHT for example) caused by the dispersion of the supply voltage value, for different values of the first correction coefficient.

Thus, in this example, it is considered that the supply voltage could have values comprised between 1.7 volts and 1.9 volts for a rated voltage of 1.8 volts.

Hence, the difference between the gain Gp of the transmission chain at 1.9 volts and the gain Gp of this transmission chain at 1.7 volts will be measured (step ST60), and that being so for different values 3, 4, 5 and 6 of the first correction coefficient G_{FF}.

First of all, one could notice that when there is no compensation, a dB variation of 2.16 is obtained which corresponds to a large variation or dispersion of the gain.

On the contrary, as soon as a compensation is applied, this variation decreases.

For example, this gain variation is equal to 0.83 for a coefficient G_{FF} equal to 3.

It is equal to 0.57 dB for a coefficient G_{FF} equal to 4.

It is equal to 0.33 dB for a coefficient GFF equal to 5.

It is equal to 0.05 dB for a coefficient GFF equal to 6.

Hence, one could see that a low variation of the gain is obtained for a coefficient G_{FF} equal to 5 and a very low variation of the gain for a coefficient G_{FF} equal to 6.

Hence, it would be possible to select the value 6 for the correction coefficient G_{FF}.

However, in some cases, it was preferable to select the value 5 for this coefficient G_{FF}, i.e., accept a gain variation slightly higher than the minimum variation, which allows being less sensitive to dynamic variations (“ripple”) of the supply voltage.

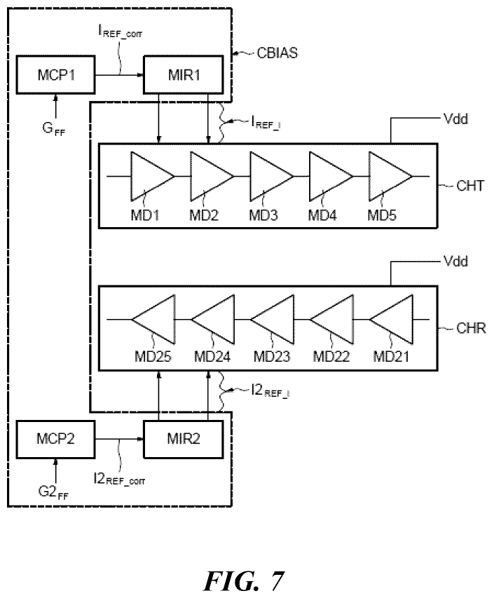

As illustrated in FIG. 7, the integrated circuit IC may include both a radiofrequency emission chain CHT and a radiofrequency reception chain CHR.

The reception chain CHR includes second radiofrequency circuits MD21-MD25 configured to be powered by the supply voltage Vdd and to be polarized based on respective second direct polarization currents I2_{REF_i}.

The reception chain CHR then has a gain forming a second physical parameter whose value may also undergo a variation resulting from the dispersion of the voltage values Vdd.

The polarization centralized circuit CBIAS may then comprise:
second compensation circuit MCP2 similar to the first compensation circuit MCP1, configured to perform an open-loop compensation of the dispersion of the voltage values, this compensation including elaborating a second corrected current I2_{REF_corr} based on the reference current I_{REF0} and a second correction coefficient G2_{FF} determined from the variation of the value of the gain of the reception chain CHR resulting from said dispersion of the voltage values.

The polarization centralized circuit then includes a second current replication circuit MIR2 configured to elaborate the second polarization currents I2_{REF_i} intended to polarize the circuits of the reception chain CHR based on the second corrected current I2_{REF_corr}.

And, of course, herein again, the correction coefficient G_{FF} and G2_{FF} could be programmable and adjusted.

In the embodiment that has just been described, the second compensation circuit MCP2 and the second current replication circuit MIR2, are distinct from the first compensation circuit MCP1 and from the first current replication circuit MIR1.

Alternatively, since the transmission and reception chains function with a time-division multiplexing, the second compensation circuit MCP2 and the second current replication circuit MIR2 could be combined with the first compensation circuit MCP1 and the first current replication circuit MIR1, so as to form the same compensation circuit and the same current replication circuit, sequentially implemented by using the first correction coefficient G_{FF} and the second coefficient G2_{FF} sequentially, according to the time-division multiplexing.

In particular, the disclosure allows reducing sensitiveness to variations of the supply voltage, of the direct polarization currents of the different circuits of the integrated circuit while keeping, where necessary, small-size polarization local structures LBS (FIG. 2) which allows reducing bulk over silicon.

The programmable centralized compensation results in improved performances compared to the solutions of the prior art.

Furthermore, this open-loop centralized compensation also reduces the maximum current consumption when the supply voltage has a maximum value which therefore results in a reduction in the maximum power consumption.

An integrated circuit, may be summarized as including at least one first electronic circuit (MDi) configured to be powered by a supply voltage (Vdd) and to be polarized based on a first direct polarization current (I_{REF_i}), the supply voltage possibly having actual values dispersed around a rated value, said at least one first circuit having at least one first physical parameter (Gp) whose value could undergo a variation resulting from said dispersion of voltage values, and a polarization centralized circuit (CBIAS) including: a first compensation circuit (MCP1) configured to perform an open-loop compensation of said dispersion of the voltage values including elaborating a first corrected current (I_{REF_corr}) based on a reference current (I_{REF0}) and a first correction coefficient (G_{FF}) determined from the variation of the value of said at least one first physical parameter, resulting from said dispersion of the voltage values; and a first current replication circuit (MIR1) configured to elaborate the first polarization current (I_{REF_i}) based on the first corrected current.

The polarization centralized circuit (CBIAS) may include a reference current source (SCR) configured to deliver the reference current and the first compensation circuit (MCP1) may be configured to: determine a voltage difference (V_{FF}) between the actual value of the supply voltage and its rated value; transform this voltage difference into a first correction current (I_{CORR}) using the first correction coefficient; and inject this first correction current in the reference current source to obtain the first corrected current.

The integrated circuit may include a reference voltage source (BG) configured to deliver a reference voltage (Vbg), and wherein the first compensation circuit (MCP1) include: a first transconductance operational amplifier (OTA1) having a first input connected to the reference voltage source and an output looped back on a second input of the first transconductance operational amplifier; a first current replication block (ETM1) connected to the output of the first transconductance operational amplifier and having a replication factor (f(G_{FF})) adjustable according to the first correction coefficient (G_{FF}); a voltage divider resistive bridge (R1, R2) having an input for receiving the supply voltage and an output, and dimensioned so as to deliver on its output a voltage equal to the reference voltage when the supply voltage present at its input, has its rated value; a second transconductance operational amplifier (OTA2) having a first input connected to the output of the divider bridge and an output looped back on a second input of the second transconductance operational amplifier; a second current replication block (ETM2) connected to the output of the second transconductance operational amplifier and having said replication factor (f(G_{FF})) adjustable according to the first correction coefficient; a node (ND) connected to the respective outputs of the two current replication blocks and able to deliver the first correction current (I_{CORR}); and the reference current source (SCR) and the first current replication circuit (MIR1) being connected to said node (ND).

The first current replication block may include two cascoded first current replication stages (ETM10, ETM11) and the second current replication block may include two cascoded second current replication stages (ETM20, ETM21).

The first correction parameter (G_{FF}) may be programmable.

The first physical parameter may be the gain of the first circuit (MDi).

The integrated circuit may include several first circuits (MDi) configured to be powered by a supply voltage and to be polarized based on respective first direct polarization currents, and the first current replication circuit are configured to elaborate these respective first polarization currents based on said corrected current.

The first circuits may form a radiofrequency emission (CHT) or reception chain and the first physical parameter may be the gain (Gp) of the emission or reception chain.

The integrated circuit may further include several second electronic circuits (MD21-MD25) configured to be powered by the supply voltage and to be polarized based on respective second direct polarization currents (I2_{REF_i}), wherein the first circuits form a radiofrequency emission chain (CHT) and the second circuits form a radiofrequency reception chain (CHR) having a gain forming a second physical parameter, whose value could undergo a variation resulting from said dispersion of voltage values, and the polarization centralized circuit (CBIAS) includes a second compensation circuit (MCP2), similar to the first compensation circuit, configured to perform an open-loop compensation of said dispersion of the voltage values including elaborating a second corrected current (I2_{REF_corr}) based on the reference current and a second correction coefficient (G2FF) determined from the variation of the value of said second physical parameter, resulting from said dispersion of the voltage values; and a second current replication circuit (MIR2) configured to elaborate the second polarization current based on the second corrected current.

A method for polarizing at least one first electronic circuit based on a first direct polarization current, said at least one first circuit (MDi) being powered by a supply voltage (Vdd) having actual values dispersed around a rated value, said at least one first circuit having at least one first physical parameter whose value could undergo a variation resulting from said dispersion of voltage values, the method may be summarized as including: an open-loop compensation of said dispersion of the voltage values, including elaborating a first corrected current (I_{REF_corr}) based on a reference current and a first correction coefficient (G_{FF}) determined from the variation of the value of said at least one first physical parameter, resulting from said dispersion of the voltage values; and elaborating the first polarization current (I_{REF_i}) based on the first corrected current.

The method may include delivering a reference current (I_{REF0}) by a reference current source and wherein said compensation includes determining a voltage difference (V_{FF}) between the actual value of the supply voltage and its nominal value; transforming this voltage difference into a first correction current using the first correction coefficient; and injecting this first correction current in the reference current source to obtain the first corrected current.

A method for determining the value of the first correction coefficient used in the integrated circuit may be summarized as including, after manufacture of the integrated circuit, a measurement (ST60) of the variation of the first physical parameter caused by the dispersion of the values of the supply voltage, for different values of the first correction coefficient, and a selection of the value of the first correction coefficient corresponding to a value desired for the variation of the first physical parameter.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An integrated circuit, comprising:
at least one first circuit configured to be powered by a supply voltage and to be polarized based on a first direct polarization current, the supply voltage having voltage values that are dispersed around a rated value, the at least one first circuit having at least one first physical parameter whose value varies as a result of the dispersion of the voltage values; and
a polarization centralized circuit including:
a first compensation circuit configured to perform open-loop compensation on the dispersion of the voltage values by at least:
determining a first corrected current based on a reference current and a first correction coefficient determined from the variation of the value of the at least one first physical parameter, resulting from the dispersion of the voltage values; and
a first current replication circuit configured to determine the first direct polarization current based on the first corrected current.

2. The integrated circuit according to claim 1, wherein the polarization centralized circuit includes a reference current source configured to deliver the reference current and the first compensation circuit is configured to:
determine a voltage difference between a value of the supply voltage and the rated value;
transform the voltage difference into a first correction current using the first correction coefficient; and
provide the first correction current to the reference current source to obtain the first corrected current.

3. The integrated circuit according to claim 2, comprising:
a reference voltage source configured to provide a reference voltage, wherein the first compensation circuit includes:
a first transconductance operational amplifier having a first input coupled to the reference voltage source and an output that feeds back to a second input of the first transconductance operational amplifier;
a first current replication circuit coupled to the output of the first transconductance operational amplifier and having a replication factor that is adjustable according to the first correction coefficient;
a voltage divider resistive bridge having an input for receiving the supply voltage and an output, wherein the voltage divider resistive bridge is dimensioned to provide, at an output, a voltage equal to the reference voltage when the supply voltage provided, at the input, has the rated value;
a second transconductance operational amplifier having a first input coupled to the output of the voltage divider resistive bridge and an output that feeds back on a second input of the second transconductance operational amplifier;
a second current replication circuit coupled to the output of the second transconductance operational amplifier and having the replication factor that is adjustable according to the first correction coefficient; and
a node coupled to the respective outputs of the first and second current replication circuits and configured to provide the first correction current, wherein the reference current source and the first current replication circuit are coupled to the node.

4. The integrated circuit according to claim 3, wherein the first current replication circuit includes two cascoded first current replication stages and the second current replication circuit includes two cascoded second current replication stages.

5. The integrated circuit according to claim 1, wherein the first correction coefficient is programmable.

6. The integrated circuit according to claim 1, wherein the first physical parameter is a gain of the at least one first circuit.

7. The integrated circuit according to claim 1, comprising:
a plurality of first circuits configured to be powered by the supply voltage and to be polarized based on respective first direct polarization currents, wherein the first current replication circuit is configured to determine the respective first direct polarization currents based on the corrected current.

8. The integrated circuit according to claim 7, wherein the plurality of first circuits form a radiofrequency emission or reception chain and the first physical parameter is a gain of the emission or reception chain.

9. The integrated circuit according to claim 8, further comprising:
a plurality of second circuits configured to be powered by the supply voltage and to be polarized based on respective second direct polarization currents, wherein the plurality of first circuits form a radiofrequency emission chain and the plurality of second circuits form a radiofrequency reception chain having a gain forming a second physical parameter, whose value varies as a result of the dispersion of the voltage values, wherein the polarization centralized circuit includes:
a second compensation circuit configured to perform open-loop compensation on the dispersion of the voltage values, the open-loop compensation including determining a second corrected current based on the reference current and a second correction coefficient determined from the variation of the second physical parameter, resulting from the dispersion of the voltage values; and
a second current replication circuit configured to determine the second direct polarization current based on the second corrected current.

10. A method for polarizing at least one first circuit based on a first direct polarization current, comprising:
powering the at least one first circuit with a supply voltage having values that are dispersed around a rated value, the at least one first circuit having at least one first physical parameter whose value varies as a result of the dispersion of voltage values;
performing open-loop compensation on the dispersion of the voltage values, performing the open-loop compensation including determining a first corrected current based on a reference current and a first correction coefficient, the first correction coefficient being determined from the variation of the value of the at least one first physical parameter, resulting from the dispersion of the voltage values; and
determining the first direct polarization current based on the first corrected current.

11. The method according to claim 10, comprising:
providing a reference current by a reference current source.

12. The method according to claim 11, wherein the open-loop compensation includes:
determining a voltage difference between a value of the supply voltage and a nominal value of the supply voltage;
transforming the voltage difference into a first correction current using the first correction coefficient; and
injecting the first correction current in the reference current source to obtain the first corrected current.

13. The method according to claim 12, comprising:
providing, by a reference voltage source, a reference voltage.

14. The method according to claim 10, wherein the first correction coefficient is programmable.

15. The method according to claim 10, wherein the first physical parameter is a gain of the at least one first circuit.

16. A method for determining a value of a first correction coefficient, comprising:
manufacturing an integrated circuit including:
at least one first circuit configured to be powered by a supply voltage and to be polarized based on a first direct polarization current, the supply voltage having voltage values that are dispersed around a rated value, the at least one first circuit having at least one first physical parameter whose value varies as a result of the dispersion of the voltage values; and
a polarization centralized circuit including:
a first compensation circuit configured to perform open-loop compensation on the dispersion of the voltage values by at least:
determining a first corrected current based on a reference current and the first correction coefficient determined from the variation of the value of the at least one first physical parameter, resulting from the dispersion of the voltage values; and
a first current replication circuit configured to determine the first direct polarization current based on the first corrected current;
after manufacturing the integrated circuit, measuring the variation of the first physical parameter caused by the dispersion of the values of the supply voltage, for different values of the first correction coefficient; and
selecting the value of the first correction coefficient corresponding to a value desired for the variation of the first physical parameter.

17. The method according to claim 16, comprising:
providing a reference current by a reference current source.

18. The method according to claim 17, wherein the open-loop compensation includes:
determining a voltage difference between a value of the supply voltage and a nominal value of the supply voltage;
transforming the voltage difference into a first correction current using the first correction coefficient; and
injecting the first correction current in the reference current source to obtain the first corrected current.

19. The method according to claim 18, comprising:
providing, by a reference voltage source, a reference voltage.

20. The method according to claim 16, wherein the first correction coefficient is programmable.
